(19) United States
(12) Patent Application Publication
(10) Pub. No.: US 2021/0119098 A1
(43) Pub. Date: Apr. 22, 2021

(54) SUBSTRATE MOUNTING METHOD AND ELECTRONIC-COMPONENT-MOUNTED SUBSTRATE

(71) Applicant: V TECHNOLOGY CO., LTD., Yokohama-shi, Kanagawa (JP)

(72) Inventors: Koichi KAJIYAMA, Yokohama-shi, Kanagawa (JP); Koichiro FUKAYA, Yokohama-shi, Kanagawa (JP); Takafumi HIRANO, Yokohama-shi, Kanagawa (JP); Yoshikatsu YANAGAWA, Yokohama-shi, Kanagawa (JP)

(73) Assignee: V TECHNOLOGY CO., LTD., Yokohama-shi, Kanagawa (JP)

(21) Appl. No.: 17/253,829

(22) PCT Filed: May 29, 2019
(86) PCT No.: PCT/JP2019/021322

§ 371 Date: Dec. 18, 2020

(30) Foreign Application Priority Data
Jun. 25, 2018 (JP) 2018-119556
Sep. 6, 2018 (JP) 2018-166936

(51) Int. Cl. H01L 33/62; H01L 23/00; H01L 33/00; H01L 21/50

(52) U.S. Cl. CPC H01L 33/62; H01L 24/80; H01L 2933/0033; H01L 33/005; H01L 21/50; H01L 24/05

(57) ABSTRACT

A substrate mounting method of an electronic component on a wiring substrate includes steps of patterning to form a conductive elastic protrusion on an electrode pad provided on the wiring substrate to correspond to a contact point of the electronic component, forming an adhesive layer made of a photosensitive thermosetting resin on the wiring substrate, lowering viscosity of the adhesive layer by heating the adhesive layer to a first temperature zone, electrically connecting the contact point of the electronic component to the electrode pad on the wiring substrate through the conductive elastic protrusion, under a state where the viscosity of the adhesive layer is lowered, by pressing the electronic component after the electronic component is positioned on the wiring substrate, and fixing the electronic component onto the wiring substrate by heating the adhesive layer to a second temperature zone higher than the first temperature zone to cure the adhesive layer.

### TECHNICAL FIELD

The present invention relates to a substrate mounting method and an electronic-component-mounted substrate for attaching an electronic component on a wiring substrate, and particularly to a substrate mounting method and an electronic-component-mounted substrate that enables an electronic component having a narrow electrode interval to be mounted.

### BACKGROUND ART

For example, as disclosed in Patent Literature 1, in a substrate connection structure of the related art, an electronic component such as a light-emitting element is provided on a mounting substrate (wiring substrate) on which a circuit or the like is formed via an adhesive material which is an anisotropic conductive material.

The adhesive disclosed in Patent Literature 1 contains conductive particles and a binder. The conductive particles electrically connect a connection electrode of an LED chip that is the light-emitting element and an electrode pad of the mounting substrate and the binder mechanically fixes the light-emitting element to the mounting substrate.

In Patent Literature 1, for example, particles of an elastic resin with a metal-film-coated surface, or gold-plated nickel (Ni) particles are used as the conductive particles contained in the adhesive. The binder of the adhesive is, for example, a thermosetting resin such as an epoxy resin or a silicone resin, or a synthetic rubber resin.

In Patent Literature 1, the adhesive preferably contains a light-reflective material. Thus, the light reflectivity of the adhesive can increase, and the light extraction efficiency of a light-emitting device increases. Specifically, titanium oxide, zirconium dioxide, potassium titanate, alumina, aluminum nitride, boron nitride, or the like can be used.

The adhesive is, for example, supplied and applied to the mounting substrate from an application nozzle.

The light-emitting element moved onto the mounting substrate by a moving mechanism of the light-emitting element is lowered by an elevating device and is placed at a predetermined location on the mounting substrate with the adhesive.

The light-emitting element on the mounting substrate is bonded to the mounting substrate by applying pressure and heat. At this time, since the adhesive material is the anisotropic conductive material, the conductive particles are interposed between the connection electrode of the light-emitting element and the pad electrode of the mounting substrate, and the light-emitting element and the mounting substrate are electrically connected.

### CITATION LIST

### Patent Literature

Patent Literature 1: WO 2014/132979 A

### SUMMARY OF INVENTION

### Technical Problem

In the substrate connection structure of the related art disclosed in Patent Literature 1, an anisotropic conductive film obtained by mixing fine metal particles with a thermosetting resin (hereinafter, “anisotropic conductive film (ACF)”) or an anisotropic conductive paste (ACP) is used as the adhesive of the anisotropic conductive material.

Since an electrode interval, however, is limited by a particle size of the metal particle, the electrode interval cannot be made narrower than about 8 μm to 10 μm at present.

To cope with a narrow electrode interval, even though the particle size of the metal particle can be made smaller, it is necessary to increase the number of particles to ensure electrical connectivity. In this case, there is a concern that the risk of causing a short circuit might increase due to the narrow electrode interval.

An electrode area becomes smaller as the electrode interval becomes narrower and a problem might occur that the number of conductive particles captured by the connection electrode (bump) of the light-emitting element varies.

Thus, it is difficult to mount a micro light-emitting diode (LED) having an outer dimension of, for example, 10 μm×30 μm or less on the mounting substrate. That is, there is a problem that a high-definition LED display cannot be manufactured.

The present invention has been made taking the above problems into account, and an object of the present invention is to provide a substrate mounting method and an electronic-component-mounted substrate that enable an electronic component having a narrow electrode interval to be mounted.

### Solution to Problem

In order to achieve the object, a substrate mounting method according to the present invention is a substrate mounting method of an electronic component on a wiring substrate. The substrate mounting method includes a step of patterning to form a conductive elastic protrusion on an electrode pad provided on the wiring substrate corresponding to a contact point of the electronic component, a step of forming an adhesive layer made of a photosensitive thermosetting resin on the wiring substrate, a step of lowering the viscosity of the adhesive layer by heating the adhesive layer to a first temperature zone, a step of electrically connecting the contact point of the electronic component to the electrode pad of the wiring substrate with the conductive elastic protrusion, under a state where the viscosity of the adhesive layer is lowered, by pressing the electronic component after the electronic component is positioned on the wiring substrate, and a step of fixing the electronic component onto the wiring substrate by heating the adhesive layer to a second temperature zone higher than the first temperature zone to cure the adhesive layer. The substrate mounting method may further include a step of forming a film made of a conductive photosensitive thermosetting resin on the contact point of the electronic component before the electronic component is pressed after the electronic component is positioned on the wiring substrate.

Alternatively, in order to achieve the object, a substrate mounting method according to the present invention is a substrate mounting method of an electronic component on a wiring substrate. The substrate mounting method includes a step of patterning to form a conductive elastic protrusion on a contact point of the electronic component corresponding to an electrode pad provided at the wiring substrate, a step of forming an adhesive layer made of a photosensitive thermosetting resin on the wiring substrate, a step of lowering the viscosity of the adhesive layer by heating the adhesive layer to a first temperature zone, a step of electrically connecting the contact point of the electronic component to the electrode pad through the elastic protrusion, under a state where the viscosity of the adhesive layer is lowered, by pressing a tip of the conductive elastic protrusion formed on the contact point of the electronic component against the electrode pad of the wiring substrate after the electronic component is positioned on the wiring substrate, and a step of fixing the electronic component onto the wiring substrate by heating the adhesive layer to a second temperature zone higher than the first temperature zone to cure the adhesive layer.

The substrate mounting method may further include a step of forming a film made of a conductive photosensitive thermosetting resin on the electrode pad of the wiring substrate before the step of forming the adhesive layer made of the photosensitive thermosetting resin on the wiring substrate.

Alternatively, in order to achieve the object, a substrate mounting method according to the present invention is a substrate mounting method of an electronic component on a wiring substrate. The substrate mounting method includes a step of patterning to form a conductive elastic protrusion on a contact point of the electronic component corresponding to an electrode pad provided on the wiring substrate, a step of forming an adhesive layer made of a photosensitive thermosetting resin on the contact point of the electronic component or the electrode pad of the wiring substrate, a step of lowering the viscosity of the adhesive layer by heating the adhesive layer to a first temperature zone, a step of electrically connecting the contact point of the electronic component to the electrode pad through the elastic protrusion, under a state where the viscosity of the adhesive layer is lowered, by pressing a tip of the conductive elastic protrusion formed on the contact point of the electronic component against the electrode pad of the wiring substrate after the electronic component is positioned on the wiring substrate and, and a step of fixing the electronic component onto the wiring substrate by heating the adhesive layer to a second temperature zone higher than the first temperature zone to cure the adhesive layer.

The adhesive layer may be a conductive photosensitive thermosetting resin in the step of forming the adhesive layer made of the photosensitive thermosetting resin on the contact point of the electronic component or the electrode pad of the wiring substrate.

It is desirable that the substrate mounting method further includes a step of forming an adhesive layer made of an insulating photosensitive thermosetting resin between the electronic component and the wiring substrate and between adjacent electrodes.

It is desirable that the elastic protrusion has a surface coated with a conductor film and is a resin columnar protrusion that electrically connects the contact point of the electronic component to the electrode pad of the wiring substrate by the conductor film or a columnar protrusion made of a conductive photoresist. The electronic component may be a micro-LED.

In order to achieve the object, an electronic-component-mounted substrate according to the present invention is an electronic-component-mounted substrate in which an electronic component is mounted on a wiring substrate. The electronic-component-mounted substrate includes the wiring substrate on which an electrode pad is formed, the electronic component that has a contact point to be connected to the electrode pad, and a conductive elastic protrusion that is formed on the contact point of the electronic component or the electrode pad of the wiring substrate and electrically connects the contact point to the electrode pad. The electrode pad of the wiring substrate and the contact point of the electronic component are bonded with a conductive photosensitive thermosetting resin formed in a bonding region.

In this case, an adhesive layer made of an insulating photosensitive thermosetting resin is desirably provided between the electronic component and the wiring substrate and between adjacent electrodes.

Alternatively, in order to achieve the object, an electronic-component-mounted substrate according to the present invention is an electronic-component-mounted substrate in which an electronic component is mounted on a wiring substrate. The electronic-component-mounted substrate includes the wiring substrate on which an electrode pad is formed, the electronic component that has a contact point to be connected to the electrode pad, and a conductive elastic protrusion that is formed on the contact point of the electronic component and electrically connects the contact point to the electrode pad. The wiring substrate and the electronic component are bonded with an insulating photosensitive thermosetting resin, and a tip of the elastic protrusion and the electrode pad are bonded with a conductive photosensitive thermosetting resin formed in a film shape on the electrode pad.

Alternatively, in order to achieve the object, an electronic-component-mounted substrate according to the present invention is an electronic-component-mounted substrate in which an electronic component is mounted on a wiring substrate. The electronic-component-mounted substrate includes the wiring substrate on which an electrode pad is formed, the electronic component that has a contact point to be connected to the electrode pad, and a conductive elastic protrusion that is formed on the electrode pad and electrically connects the contact point to the electrode pad. The wiring substrate and the electronic component are bonded with an insulating photosensitive thermosetting resin, and a tip of the elastic protrusion and the electrode pad are bonded with a conductive photosensitive thermosetting resin formed in a film shape on the contact point.

It is desirable that the elastic protrusion has a surface coated with a conductor film and is a resin columnar protrusion that electrically connects the contact point of the electronic component to the electrode pad of the wiring substrate through the conductor film or is a columnar protrusion made of a conductive photoresist. The electronic component may be a micro-LED.

According to such a substrate mounting method and electronic-component-mounted substrate, since the elastic protrusion on the electrode pad of the wiring substrate can be formed by applying a photolithography step, it is possible to secure high accuracy in location and shape, to easily form the elastic protrusion even though intervals between the contact points of the electronic components become narrower than about 10 μm, and to manufacture a highly accurate micro-LED display or the like.

When the elastic protrusion and the contact point of the electronic component (or the electrode pad on the wiring substrate) are connected, since the adhesive is in the first temperature zone and is soft, the adhesive does not hinder electrical connection at a connection portion thereof. Thus, it is possible to mount electronic components such as a plurality of micro-LEDs on the wiring substrate by performing easy and reliable electrical connection.

### Advantageous Effects of Invention

According to the present invention, it is possible to provide a substrate mounting method and an electronic-component-mounted substrate that enable an electronic component having a narrow electrode interval to be mounted.

### BRIEF DESCRIPTION OF DRAWINGS

FIG. 1 is a schematic plan view illustrating a micro-LED display to which a substrate mounting method according to the present invention is applied.

FIG. 2 is an enlarged cross-sectional view of the main part of FIG. 1.

FIG. 3 is a schematic cross-sectional view illustrating a substrate connection structure formed by the substrate mounting method according to the present invention.

FIGS. 4A to 4D show a process chart for describing a first embodiment of the substrate mounting method according to the present invention.

FIG. 5 is a schematic graph illustrating characteristics of a photosensitive thermosetting resin adhesive used in the substrate mounting method according to the present invention.

FIGS. 6A to 6B show a process chart for describing a second embodiment of the substrate mounting method according to the present invention.

FIGS. 7A to 7B show a process chart for describing a third embodiment of the substrate mounting method according to the present invention.

FIG. 8 is a process chart for describing a fourth embodiment of a substrate mounting method according to the present invention.

FIGS. 9A to 9C show a process chart for describing a fifth embodiment of the present invention.

FIGS. 10A to 10B show a process chart for describing a sixth embodiment of the present invention.

FIGS. 11A to 11E show another process chart for describing the sixth embodiment of the present invention.

FIGS. 12A to 12B show a process chart for describing a seventh embodiment according to the present invention.

FIGS. 13A to 13B show a process chart for describing formation of a fluorescent light-emitting layer array of the micro-LED display.

FIGS. 14A to 14B show a process chart for describing assembly of the wiring substrate of the micro-LED display and the fluorescent light-emitting layer array.

### DESCRIPTION OF EMBODIMENTS

### First Embodiment

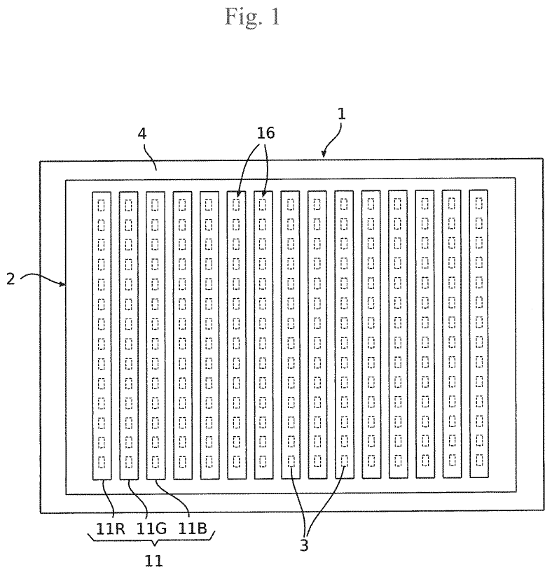

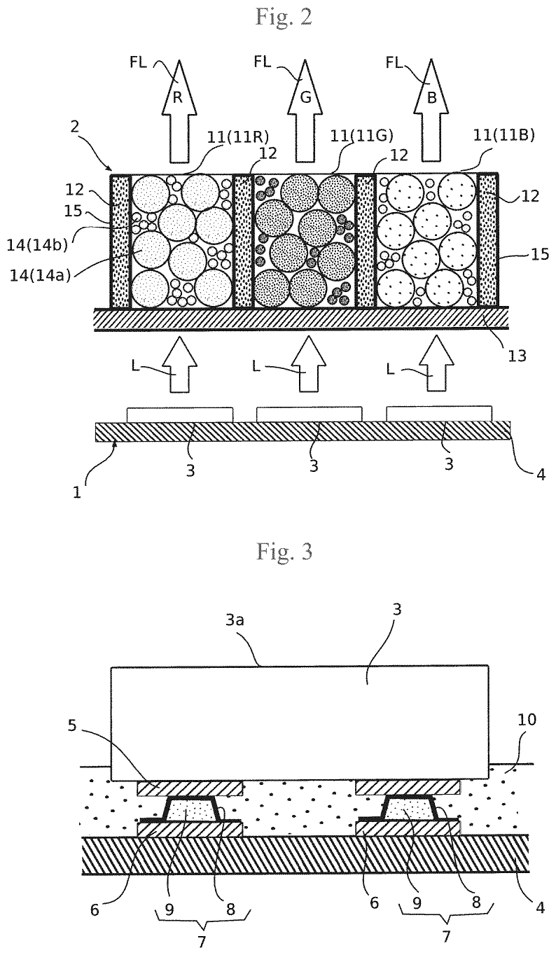

Hereinafter, a first embodiment of a substrate mounting method according to the present invention will be described with reference to the drawings. FIG. 1 is a schematic plan view illustrating a micro-LED display to which the substrate mounting method according to the present invention is applied, FIG. 2 is an enlarged cross-sectional view of a main part of FIG. 1, and FIG. 3 is a schematic cross-sectional view illustrating a substrate connection structure (electronic-component-mounted substrate) formed by the substrate mounting method according to the present invention.

The micro-LED display illustrated in FIG. 1 displays a color image, and includes an LED array substrate 1 and a fluorescent light-emitting layer array 2. The LED array substrate 1 includes a plurality of micro-LEDs 3 as electronic components arranged in a matrix as illustrated in FIG. 1, and a video signal from a drive circuit externally provided is supplied to each micro-LED 3. The plurality of micro-LEDs 3 is disposed on a wiring substrate 4 on which wirings for turning on/off the micro-LEDs 3 by individually driving the turning-on/off of the micro-LEDs.

Specifically, electrode pads 6 are provided on the wiring substrate 4 to correspond to contact points 5 on a side opposite to a light extraction surface 3a of the micro-LED 3 at an installation location of each micro-LED 3, as illustrated in FIG. 3. Each electrode pad 6 is connected to an external drive circuit by a wiring (not illustrated).

As illustrated in FIG. 1, the plurality of micro-LEDs 3 is provided on the wiring substrate 4. The micro-LED 3 emits light of a wavelength band from ultraviolet to blue is manufactured by using gallium nitride (GaN) as a principal material. The LED may be those emitting near-ultraviolet light having a wavelength of, for example, 200 nm to 380 nm, or the LED may be those emitting blue light having a wavelength of, for example, 380 nm to 500 nm.

Specifically, as illustrated in FIG. 3, the micro-LED 3 is formed such that the contact points 5 of the micro-LED 3 and the electrode pads 6 are electrically connected via conductive elastic protrusions 7 (resin bump) patterned on the electrode pads 6 of the wiring substrate 4.

More specifically, the elastic protrusion 7 is a resin columnar protrusion 9 whose surface is coated with a conductor film 8 having good conductivity such as gold or aluminum. Alternatively, the columnar protrusion 9 may be made of a conductive photoresist prepared by adding conductive fine particles such as silver into photoresist or forming with a conductive photoresist containing a conductive polymer.

The substrate connection structure is composed of the contact points 5 of the micro-LED 3, the electrode pads 6 of the wiring substrate 4, and the elastic protrusions 7. It is shown in FIG. 3 that the columnar protrusion 9 having the surface coated with the conductor film 8 is formed as an example of the elastic protrusion 7, but the elastic protrusion 7 may be made of the conductive photoresist as described above.

Further, as illustrated in FIG. 3, the micro-LED 3 is adhesively fixed onto the wiring substrate 4 with an adhesive layer 10 provided around the electrode pads 6 of the wiring substrate 4. The adhesive layer 10 illustrated in FIG. 3 is in a state in which an adhesive made of a photosensitive thermosetting resin is cured.

A fluorescent emitting layer array 2 is provided on the micro LEDs 3 as shown in FIG. 2.

The fluorescent emitting layer array 2 includes a plurality of fluorescent emitting layers 11 (11R, 11G, 11B) each of which converts the excitation light L from the micro LEDs 3 into fluorescent FL having a wavelength corresponding to the color of R, G, and B. As shown in FIG. 2, the fluorescent emitting layer 11 that correspond to each color of red, green, and blue are provided on an upper surface of a transparent substrate, being partitioned by separation walls 12. The term “upper” always means the “displaying surface side” in the description despite the state of arrangement.

More specifically, the fluorescent light-emitting layer 11 is obtained by mixing and dispersing a fluorescent dye 14a having a large particle size of the order of several tens of microns and a fluorescent dye 14b having a small particle size of the order of several tens of nanometers in a photoresist film. The fluorescent light-emitting layer 11 may contain only the fluorescent dyes 14a having the large particle size. However, in this case, a filling rate of the fluorescent dyes 14a is reduced, and thus, leak light of the excitation light L to the display surface side increases. Meanwhile, when the fluorescent light-emitting layer 11 contains only the fluorescent dyes 14b having the small particle size, there is a problem that stability such as light resistance deteriorates. Accordingly, as described above, by preparing the fluorescent light-emitting layer 11 to contain a mixture mainly of the fluorescent dyes 14a having the large particle size with the fluorescent dyes 14b having the small particle size, this can prevent the excitation light L from leaking to the display surface side and improve the luminous efficiency.

In this case, a mixing ratio in volume of the fluorescent dyes 14 having different particle sizes is desirably a ratio of 10 to 50 Vol % of the fluorescent dyes 14b having the small particle size to 50 to 90 Vol % of the fluorescent dyes 14a having the large particle size.

Although it is illustrated in FIG. 1 that the fluorescent light-emitting layers 11 corresponding to the respective colors are provided in a stripe shape, the fluorescent light-emitting layers may be provided so as to individually correspond to the micro-LEDs 3.

The partition walls 12 provided so as to surround the fluorescent light-emitting layers 11 corresponding to the respective colors separate the fluorescent light-emitting layers 11 corresponding to the respective colors from each other, and are made of, for example, a transparent photosensitive resin. In order to increase the filling rate of the fluorescent dyes 14a having the large particle size in the fluorescent light-emitting layer 11, a high aspect material capable of realizing an aspect ratio of height to width of 3 or more is desirably used as the partition wall 12. An example of such a high aspect ratio material is a photoresist of SU-8 3000 manufactured by Nippon Kayaku Co., Ltd.

Metal films 15 are respectively provided on surfaces of the partition walls 12 as illustrated in FIG. 2. The metal film 15 prevents the excitation light L and the fluorescence light FL emitted by the fluorescent light-emitting layer 11 excited by the excitation light L from being transmitted through the partition wall 12 and being mixed with the fluorescence light FL of an adjacent fluorescence luminous layer 11 of another color. Thus, the metal film 15 is formed with thickness, with which the excitation light L and the fluorescence light FL can be sufficiently blocked.

In this case, a thin film such as aluminum or aluminum-alloy having high reflectivity of the excited light L is preferable as a metal film 15.

The excited light L passing through the fluorescent light-emitting layer 11 toward the separation wall 12 is reflected toward the fluorescent light-emitting layer 11 by a metal film 15 such as aluminum. With this, the light-emitting efficiency of the fluorescent light-emitting layer 11 is improved by utilizing the excited light L for the light-emitting action of the fluorescent light-emitting layer 11. The thin film coated on the surface of the partition wall 12 is not limited to the metal film 15 that reflects the excitation light L and the fluorescence light FL, and may be a film that absorbs the excitation light L and the fluorescence light FL.

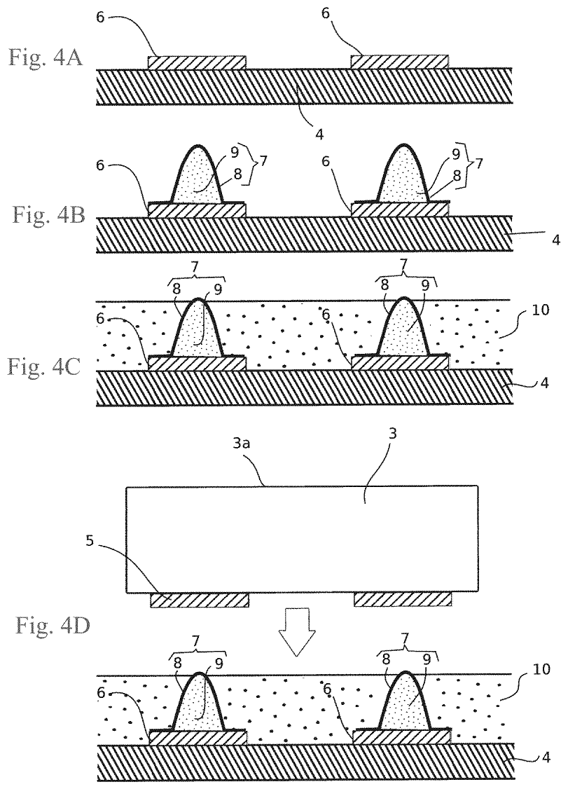

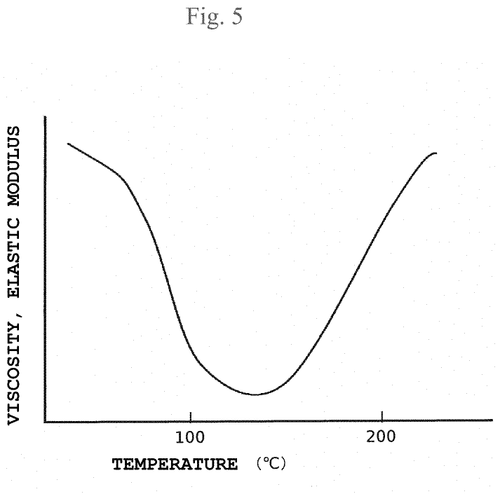

Next, a method of manufacturing the micro-LED display formed in this manner will be described. First, a substrate mounting method of the micro-LEDs 3 over the wiring substrate 4 (a method of manufacturing the LED array substrate 1) will be described with reference to FIGS. 4A to 4D.

As illustrated in FIG. 4A, the plurality of electrode pads 6 is formed at locations on the wiring substrate 4 corresponding to the contact points 5 of the plurality of micro-LEDs 3. This wiring substrate 4 can be formed by a publicly known technique.

Next, the columnar protrusions 9 are patterned on the electrode pads 6 as illustrated in FIG. 4B by applying a photoresist for a photo spacer onto the entire upper surface of the wiring substrate 4 and exposing the photoresist with a photomask and developing. As illustrated in the diagram, the columnar protrusions 9 are formed such that the cross-section of a tip portion is to be semi-elliptical or semicircular.

Thereafter, the elastic protrusions 7 are formed by coating conductor films 8 having good conductivity such as gold or aluminum on the columnar protrusions 9 and the electrode pads 6, by sputtering, vapor deposition, or the like. The conductor film 8 may have two or more layers, if necessary, in consideration of adhesiveness to the resin.

The method of forming the conductor films 8 will be described in more detail. A photoresist layer is formed by photolithography at peripheral portions, excluding the electrode pads 6, before the conductor film 8 is formed. After the conductor film 8 is formed, the photoresist layer dissolves when being developed. Accordingly, the excess conductor films 8 on the photoresist layer are lifted off and the conductor films 8 are formed only on the columnar protrusions 9 and the electrode pads 6.

The elastic protrusions 7 may be the columnar protrusions 9 made of the conductive photoresist obtained by adding the conductive particles such as silver to the photoresist or the conductive photoresist containing the conductive polymer. In this case, the elastic protrusions 7 are patterned as the columnar protrusions 9 on the electrode pads 6 by applying a conductive photoresist with a predetermined thickness onto the entire upper surface of the wiring substrate 4 and exposing the conductive photoresist with a photomask and developing.

As described above, since the elastic protrusions 7 can be formed by applying a photolithography process, it is possible to secure high accuracy in position and shape and to easily form the elastic protrusions even when intervals between the contact points 5 of the micro-LEDs 3 become narrower than about 10 μm.

Since the elastic protrusions 7 are in contact with the contact points 5 of the micro-LEDs 3 by elastic deformation caused by pressurization of the micro-LEDs 3, even though the plurality of micro-LEDs 3 is simultaneously pressed as will be described later, the respective contact points 5 of the respective micro-LEDs 3 can be reliably brought into contact with the elastic protrusions 7.

Next, as illustrated in FIG. 4C, the adhesive layer 10 is formed by applying the photosensitive thermosetting resin onto the entire upper surface of the wiring substrate 4. A thickness of the adhesive layer 10 formed by being applied at this time is approximately a height dimension including the electrode pads 6 and the elastic protrusions 7 of the wiring substrate 4, and is preferably a thickness with which the tip portions of the elastic protrusions 7 slightly protrude from a surface of the adhesive layer 10.

Here, the photosensitive thermosetting resin forming the adhesive layer 10 has characteristics of a curve schematically illustrated in a graph of FIG. 5. That is, viscosity (elastic modulus) gradually decreases and is softened until a temperature reaches a first temperature zone (for example, 100° C. to 120° C.) by heating. However, the photosensitive thermosetting resin starts curing when the temperature exceeds a maximum softening point, and a practical curing speed is obtained when the temperature reaches a second temperature zone (for example, 180° C. or higher). It is possible to cure the photosensitive thermosetting resin in a short time because of such characteristics.

In the substrate mounting method according to the present invention, the viscosity of the adhesive layer 10 is reduced by heating the adhesive layer 10 to the first temperature zone (for example, 100° C. to 120° C.) in a temperature controllable heating furnace.

The first temperature zone may be set according to the characteristics of the photosensitive thermosetting resin (adhesive) to be used.

Subsequently, while maintaining the adhesive layer 10 in a low-viscosity state, the micro-LEDs 3 are positioned and arranged such that the contact points 5 and the electrode pads 6 on the wiring substrate 4 match each other as illustrated in FIG. 4D. Here, the micro-LEDs 3 are formed on a sapphire wafer (not illustrated) at regular intervals, or are arranged at regular intervals by being formed on the sapphire wafer and being then transferred to an adhesive sheet.

When the micro-LEDs 3 are positioned as described above, the contact points 5 of the micro-LEDs 3 and the electrode pads 6 of the wiring substrate 4 are electrically connected through the conductive elastic protrusions 7 by pressing the sapphire wafer (micro-LED wafer) or the adhesive sheet against the wiring substrate 4.

Until all the elastic protrusions 7 come into contact with the contact points 5 of the micro-LEDs 3, the tips of the elastic protrusions 7 coming into contact with the micro-LEDs 3 crushes, and thus, a height difference between the elastic protrusions 7 is absorbed.

As a result, the electrical connection between all the micro-LEDs and the wiring substrate is secured.

Next, the temperature of the adhesive layer 10 is raised to the second temperature zone (for example, 180° C. or higher) by heating the adhesive layer. This second temperature zone may be set according to the characteristics of the photosensitive thermosetting resin (adhesive) to be used as described above.

By this heat treatment, the adhesive layer 10 is thermally cured, and the micro-LEDs 3 are adhesively fixed onto the wiring substrate 4.

After the micro-LEDs 3 are adhesively fixed onto the wiring substrate 4, the sapphire wafer or the adhesive sheet attached to the light extraction surfaces 3a side of the micro-LEDs 3 is peeled off, and thus, the mounting (lifting-off) of the micro-LEDs 3 on the wiring substrate 4 side is completed.

### Second Embodiment

In the first embodiment, it is described that the columnar protrusions 9 are formed on the electrode pads 6 of the wiring substrate 4 and the elastic protrusions 7 are formed by coating the conductor film 8 on the columnar protrusions, but the substrate mounting method according to the present invention is not limited thereto.

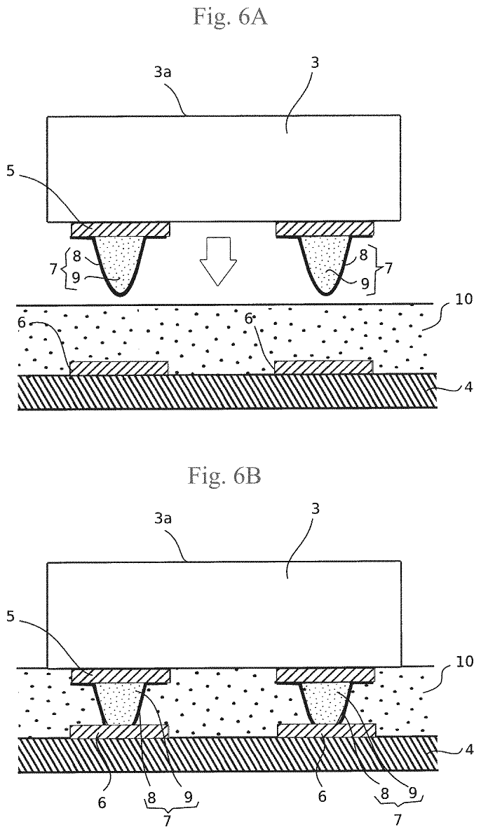

For example, as illustrated in FIG. 6A, the elastic protrusions 7 may be formed on the contact points 5 of the micro-LED 3. A second embodiment illustrating a mounting method in this case will be described below.

First, the columnar protrusions 9 are patterned on the contact points 5 by applying a photoresist for a photo spacer onto the entire electrode surface (contact point 5 side) of the micro-LED 3 and exposing with a photomask and developing. As illustrated in the diagram, the columnar protrusions 9 are formed such that cross sections of tip portions are semi-elliptical. The elastic protrusions 7 are formed by forming the conductor film 8 having good conductivity such as gold or aluminum by sputtering, vapor deposition, or the like on the columnar protrusions 9 and the contact points 5.

Next, as illustrated in FIG. 6A, the adhesive layer 10 having a predetermined thickness is formed by applying a photosensitive thermosetting resin onto the entire upper surface of the wiring substrate 4.

Thereafter, following the similar procedure as in the first embodiment, the contact points 5 and the electrode pads 6 of the micro-LEDs 3 are electrically connected through the conductive elastic protrusions 7 by applying pressure from the light extraction surfaces 3a side of the micro-LEDs 3 to the adhesive layer, and thus, the micro-LEDs 3 are mounted on the wiring substrate 4 as illustrated in FIG. 6B.

### Third Embodiment

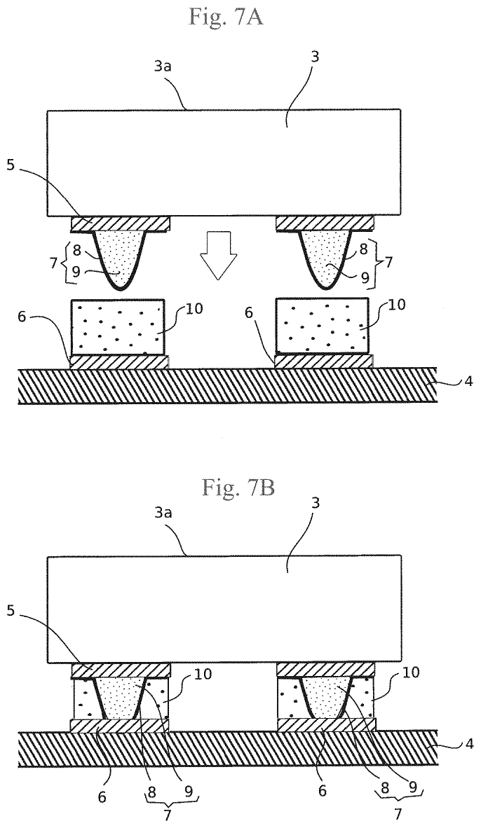

When the elastic protrusions 7 are formed on the side of the micro-LEDs 3 as in the second embodiment, the micro-LEDs 3 may be mounted on the wiring substrate 4 after the adhesive layer 10 is formed only on the electrode pads 6 of the wiring substrate 4 as illustrated in time series in FIGS. 7A and 7B.

### Fourth Embodiment

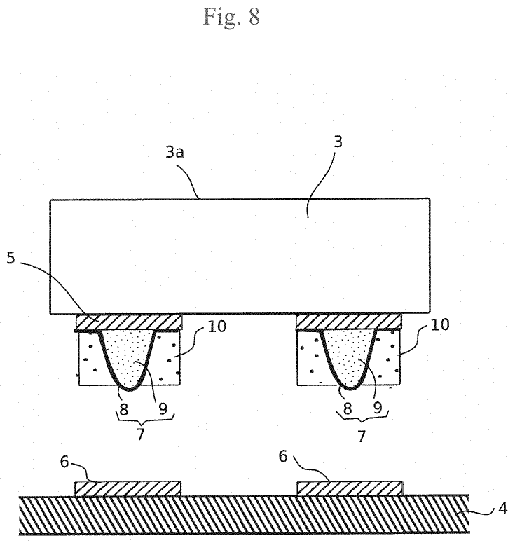

Alternatively, as illustrated in FIG. 8, the micro-LEDs 3 may be mounted on the wiring substrate 4 after the adhesive layer 10 is formed so as to cover the elastic protrusions 7 formed on the micro-LED 3.

The adhesive layer 10 may be conductive when the adhesive layer 10 is formed only on the electrode pads 6 as in the third embodiment (FIGS. 7A to 7B) or when the adhesive layer 10 is formed so as to cover only the elastic protrusions 7 as in the fourth embodiment (FIG. 8).

Here, when the entire surface within the substrate is viewed, a minute gap is formed between the elastic protrusion 7 and the electrode pad 6 at a part of the substrate depending on physical factors of equipment, a temperature, and a state of a target object; there is a possibility that the elastic protrusion and the electrode pad might not come in contact with each other. Namely, the contact point 5 of the micro-LED 3 and the electrode pad 6 are not electrically connected when the adhesive layer 10 is an insulating layer.

However, when the adhesive layer 10 provided in a bonding region (adjacent region) between the contact point of the micro-LED 3 and the electrode pad 6 is conductive, the contact point 5 of the micro-LED 3 and the electrode pad 6 can be electrically connected, even though the minute gap is formed between the elastic protrusion 7 and the electrode pad 6.

In order to allow the adhesive layer 10 in the bonding region to be conductive, conductive particles (for example, carbon particles) may be blended into the photosensitive thermosetting resin.

The blending of the conductive particles in the conductive photosensitive thermosetting resin may be performed such that the adhesive layer has conductivity in the minute gap between the elastic protrusion 7 and the electrode pad 6 without affecting adhesion performance.

In the configuration of FIGS. 7A to 7B and 8, when the adhesive layer 10 provided in the bonding region between the electrode pad 6 and the contact point 5 is made of a conductive photosensitive thermosetting resin, a height of the elastic protrusion 7 may be slightly lower than a height of the adhesive layer 10.

The conductive photosensitive thermosetting resin (adhesive layer 10) may protrude onto the wiring substrate 4 as long as a short circuit does not occur between adjacent electrodes.

### Fifth Embodiment

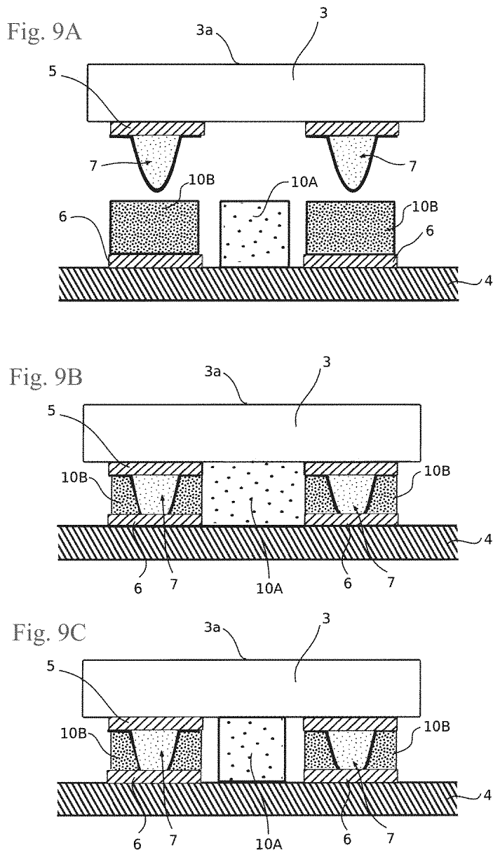

When the adhesive layer 10 is made of the conductive photosensitive thermosetting resin in the configuration of FIGS. 7A to 7B and 8, an insulating photosensitive thermosetting resin 10A may be provided between adjacent electrodes as illustrated in FIG. 9A in order to reinforce adhesion and prevent the short circuit between the adjacent electrodes; an order of applying the insulating photosensitive thermosetting resin 10A and a conductive photosensitive thermosetting resin 10B is not limited.

In this case, when the micro-LED 3 is mounted on the wiring substrate 4, a mounting state is as illustrated in, for example, FIGS. 9B and 9C. That is, the applied insulating photosensitive thermosetting resin 10A and conductive photosensitive thermosetting resins 10B come in contact with each other as illustrated in, for example, FIG. 9B (may partially come in contact with each other), or are separated as illustrated in FIG. 9C.

Although FIGS. 9A to 9C illustrate an example in which an adhesive is applied to the wiring substrate 4, the state after the micro-LEDs 3 are mounted is the same for the above case and the case where the adhesive is applied to micro-LED 3.

In the configuration of FIGS. 9A to 9C, since the adhesive layer 10 provided in the bonding region between the electrode pad 6 and the contact point 5 is the conductive photosensitive thermosetting resin 10B, the elastic protrusion 7 may be formed so as to have a height slightly lower than a height of the conductive photosensitive thermosetting resin 10B (adhesive layer 10).

As long as the short circuit does not occur between the adjacent electrodes, the conductive photosensitive thermosetting resins 10B may protrude onto the wiring substrate 4.

### Sixth Embodiment

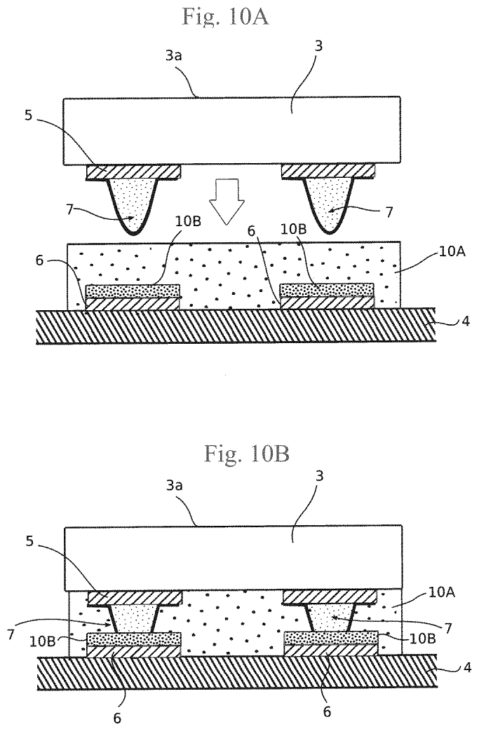

As described above, when the conductive photosensitive thermosetting resin is used as a countermeasure when the minute gap is formed between the elastic protrusion 7 and the electrode pad 6, the micro-LED may be mounted on the wiring substrate as illustrated in FIGS. 10A and 10B.

That is, as shown in the figures, the conductive photosensitive thermosetting resin 10B is formed on the electrode pad 6 in a film shape having a predetermined thickness (set to be thicker than the minute gap to be assumed), and the insulating photosensitive thermosetting resin 10A is provided in a region in which the micro-LED 3 adheres to the wiring substrate 4.

With such a configuration, even when the tip of the elastic protrusion 7 and the electrode pad 6 do not come in contact with each other due to the minute gap formed therebetween in a part of the substrate, the tip of the elastic protrusion 7 and the electrode pad 6 can be bonded by the conductive photosensitive thermosetting resin 10B, and can be electrically connected to each other.

The procedure for forming the insulating photosensitive thermosetting resin 10A and the conductive photosensitive thermosetting resin 10B on the wiring substrate 4 as illustrated in FIG. 10A may be as follows.

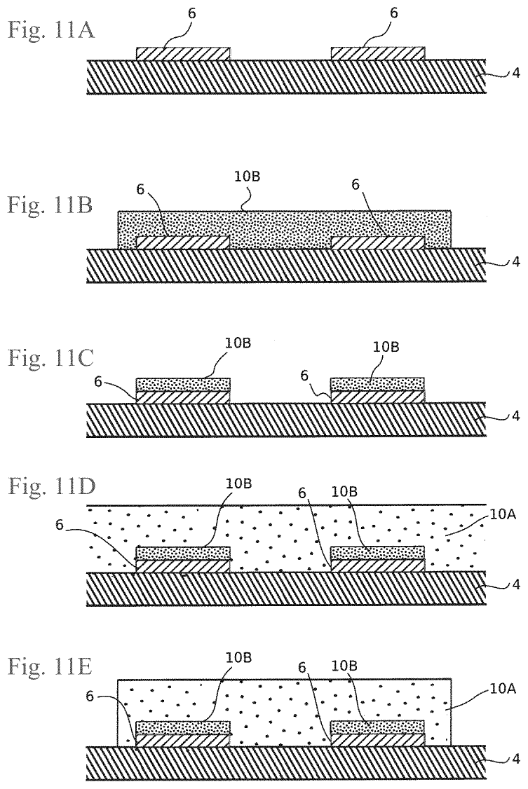

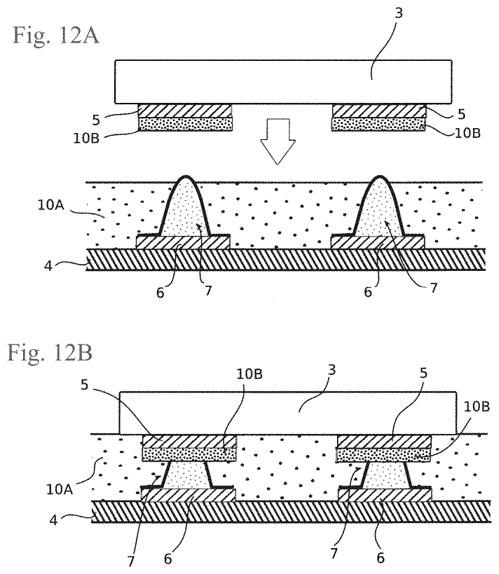

First, the electrode pads 6 are formed on the wiring substrate 4 as illustrated in FIG. 11A, and the conductive photosensitive thermosetting resins 10B is applied and formed on the upper surface of the substrate 4 as illustrated in FIG. 11B.

Subsequently, films of the conductive photosensitive thermosetting resin 10B having a predetermined thickness are formed only on the electrode pads 6 as shown in FIG. 11C by exposing the conductive photosensitive thermosetting resin with a mask having patterns according to the arrangement and shape of the electrode pads 6, subsequently developing and exposing the exposed conductive photosensitive thermosetting resin, and removing the photoresist in sequence.

As illustrated in FIG. 11D, the insulating photosensitive thermosetting resin 10A is applied and formed on the wiring substrate 4, exposed through a patterned mask according to the arrangement and shape of the micro-LEDs 3, developed, and etched, and then the photoresist is removed in sequence.

Accordingly, as illustrated in FIG. 11E, the photosensitive thermosetting resin 10A corresponding to an attachment range of the micro-LED 3 is formed.

### Seventh Embodiment

It has been described in the sixth embodiment illustrated in FIGS. 10A to 10B that the conductive photosensitive thermosetting resins 10B are formed on the electrode pads 6 in the film shape having the predetermined thickness. However, the films of the conductive photosensitive thermosetting resin 10B may be formed on the contact points 5 of the micro-LED 3 instead of the electrode pads 6 as illustrated in FIGS. 12A and 12B.

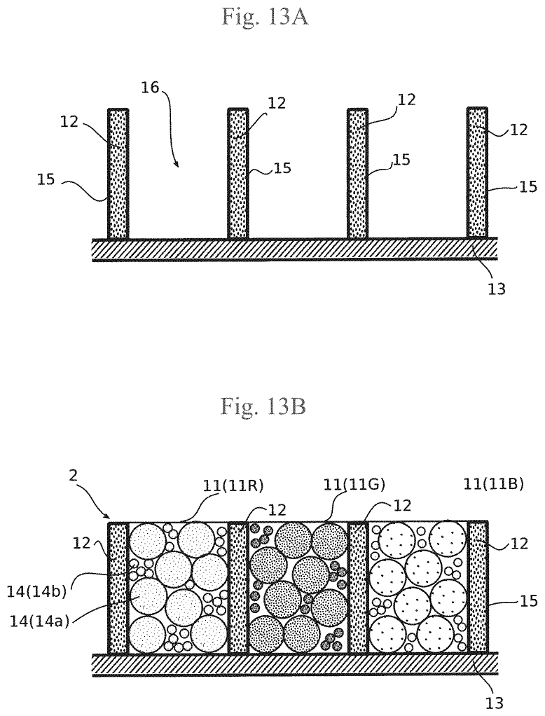

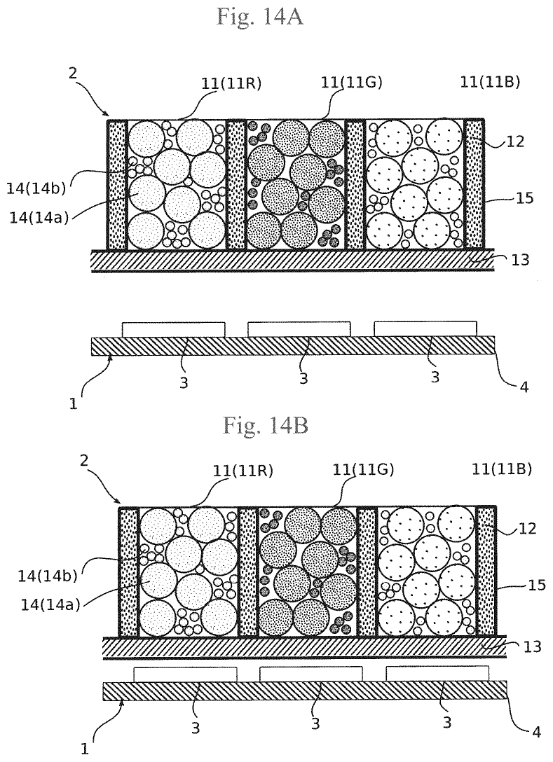

Subsequently, the formation of the fluorescent light-emitting layer array 2 will be described with reference to FIGS. 13A to 13B and 14A to 14B.

First, as illustrated in FIG. 13A, a transparent photosensitive resin for the partition wall 12 is applied onto the transparent substrate 13 formed by using, for example, a glass substrate or a plastic substrate such as an acrylic resin that at least transmits light at least from blue wavelength to near-ultraviolet wavelength band.

Thereafter, for example, the photosensitive resin is exposed with a photomask and developed, stripe-shaped openings 16 are formed so as to correspond to formation locations of the fluorescent light-emitting layers 11 as illustrated in FIG. 1, and the transparent partition wall 12 having an aspect ratio of height to width of 3 or more is formed with a minimum height of about 10 μm.

In this case, an example of the photosensitive resin to be used is desirably a high aspect material such as SU-83000 manufactured by Nippon Kayaku Co., Ltd.

Subsequently, for example, the metal films 15 such as aluminum or aluminum alloy are formed with a predetermined thickness from the side of the partition wall 12 formed on the transparent substrate 13 by applying a publicly known film forming technique such as sputtering. After the films are formed, the metal films 15 deposited on the transparent substrate 13 at bottom portions of the openings 16 surrounded by the partition wall 12 are removed by laser irradiation.

Alternatively, a photoresist or the like may be applied onto the surface of the transparent substrate 13 at the bottom portions of the openings 16 with a thickness of several μm using an inkjet method, for example, before the films are formed, and the photoresist and the metal film 15 on the photoresist may be lifted off and removed after the metal films 15 are formed. In this case, as a matter of course, a chemical solution that does not damage the resin of the partition wall 12 is selected as a photoresist dissolving solution used for lifting off.

Subsequently, as illustrated in FIG. 13B, after a photoresist containing the fluorescent dyes 14 for, for example, red color is applied to the plurality of openings 16 which is surrounded by the partition walls 12 and corresponds to, for example, the red color using an inkjet method, for example, a red fluorescent light-emitting layer 11R is formed by irradiating the photoresist with ultraviolet light and curing the photoresist. Alternatively, after a photoresist containing the fluorescent dyes 14 for the red color is applied so as to cover the transparent substrate 13, the red fluorescent light-emitting layer 11R is formed in the plurality of openings 16 corresponding to the red color by exposing with a photomask and developing the photoresist. In this case, the photoresist is obtained by mixing and dispersing the fluorescent dyes 14a having the large particle size and the fluorescent dyes 14b having the small particle size, and the mixing ratio thereof is a ratio of 10 to 50 Vol % of the fluorescent dyes 14b having the small particle size to 50 to 90 Vol % of the fluorescent dyes 14a having the large particle size.

Similarly, after a photoresist containing the fluorescent dyes 14 for, for example, green color is applied to the plurality of openings 16 which is surrounded by the partition walls 12 and corresponds to, for example, the green color using an inkjet method, for example, a green fluorescent light-emitting layer 11G is formed by irradiating the photoresist with ultraviolet light and curing the photoresist. Alternatively, the green fluorescent light-emitting layer 11G may be formed in the plurality of openings 16 corresponding to the green color by similarly exposing with a photomask and developing the photoresist containing the fluorescent dyes 14 for the green color applied on the entire upper surface of the transparent substrate 13.

Similarly, after a photoresist containing the fluorescent dyes 14 for, for example, blue color is applied to the plurality of openings 16 which is surrounded by the partition wall 12 and corresponds to, for example, the blue color using an inkjet method, for example, a blue fluorescent light-emitting layer 11B is formed by irradiating the photoresist with ultraviolet light and curing the photoresist. In this case, the blue fluorescent light-emitting layer 11B may be formed in the plurality of openings 16 corresponding to the blue color by similarly exposing with the photomask and developing the photoresist containing the fluorescent dyes 14 for the blue color applied to the entire upper surface of the transparent substrate 13.

In this case, an antireflection film that prevents reflection of external light may be provided on the displaying surface side of the fluorescent light-emitting layer array 2. Black paint may be applied onto the metal film 15 on the displaying surface side of the partition wall 12. Owing to the use of these measures, the reflection of the external light on the displaying surface can be reduced and contrast can be improved.

Subsequently, a process of assembling the LED array substrate 1 and the fluorescent light-emitting layer array 2 is performed.

First, as illustrated in FIG. 14A, the fluorescent light-emitting layer array 2 is positioned and arranged on the LED array substrate 1. Specifically, alignment is performed such that the fluorescent light-emitting layers 11 corresponding to the respective colors of the fluorescent light-emitting layer array 2 are located on the corresponding micro-LEDs 3 on the LED array substrate 1 by using an alignment mark formed on the LED array substrate 1 and an alignment mark formed on the fluorescent light-emitting layer array 2.

When the alignment of the LED array substrate 1 and the fluorescent light-emitting layer array 2 is completed, the micro-LED display is completed by bonding the LED array substrate 1 and the fluorescent light-emitting layer array 2 by an adhesive (not illustrated) as illustrated in FIG. 14B.

As described above, according to the embodiments of the present invention, the elastic protrusions 7 on the electrode pads 6 of the wiring substrate 4 are formed by applying the photolithography process.

Thus, it is possible to secure high accuracy in location and shape, to easily form the elastic protrusions even though the intervals between the contact points 5 of the micro-LED 3 become narrower than about 10 μm, and to manufacture a highly accurate micro-LED display or the like.

When the micro-LEDs 3 are mounted on the wiring substrate 4, after the adhesive layer 10 is formed on the entire upper surface of the wiring substrate 4 (or on a lower surface side of the micro-LED 3) as described above and the viscosity of the adhesive layer is lowered by heating, the contact points 5 of the positioned micro-LEDs 3 are connected to the elastic protrusions 7 on the electrode pads 6 by being pressed against the elastic protrusions. Here, since the adhesive is soft when the elastic protrusions 7 and the contact points 5 of the micro-LEDs 3 are connected, the adhesive does not hinder electrical connection at a connection portion thereof.

As a result, the plurality of micro-LEDs 3 can be mounted on the wiring substrate 4 by performing electrical connection easily and reliably. Thereafter, heat treatment for curing the adhesive is performed.

Although it has been described in the embodiment that the cross section of the tip of the elastic protrusion 7 is semi-elliptical (or semi-circular), the tip shape thereof is not limited in the present invention. Preferably, the tip shape may be a shape (including a trapezoid) of which a diameter is decreasing toward the tip, but may be a column of which a diameter is not changed toward the tip.

In the fluorescent light-emitting layer array 2, the fluorescent light-emitting layers 11 corresponding to the respective colors of red, green and blue are provided on the transparent substrate 13 in a state of being partitioned by the partition walls 12.

However, the micro-LED display to which the substrate mounting method according to the present invention is applied is not limited to the configuration.

Although it has been described that the electronic component is the micro-LED 3, the present invention is not limited thereto, and the electronic component may be a semiconductor component or may be another micro electronic component.

### REFERENCE SIGN LIST

3 micro-LED (electronic component)
4 wiring substrate
5 contact point
6 electrode pad
7 elastic protrusion
8 conductor film
9 columnar protrusion
10 adhesive layer
10A insulating photosensitive thermosetting resin
10B conductive photosensitive thermosetting resin

1. A substrate mounting method of an electronic component on a wiring substrate, the substrate mounting method comprising steps of:
patterning to form a conductive elastic protrusion on an electrode pad provided on the wiring substrate corresponding to a contact point of the electronic component;
forming an adhesive layer made of a photosensitive thermosetting resin on the wiring substrate;
lowering viscosity of the adhesive layer by heating the adhesive layer to a first temperature zone;
electrically connecting the contact point of the electronic component to the electrode pad on the wiring substrate through the conductive elastic protrusion, under a state where the viscosity of the adhesive layer is lowered, by pressing the electronic component after the electronic component is positioned on the wiring substrate; and
fixing the electronic component onto the wiring substrate by heating the adhesive layer to a second temperature zone higher than the first temperature zone to cure the adhesive layer.

2. The substrate mounting method according to claim 1, further comprising:
a step of forming a film made of a conductive photosensitive thermosetting resin on the contact point of the electronic component before the electronic component is pressed after the electronic component is positioned on the wiring substrate.

3. A substrate mounting method of an electronic component on a wiring substrate, the substrate mounting method comprising steps of:
patterning to form a conductive elastic protrusion on a contact point of the electronic component corresponding to an electrode pad provided on the wiring substrate;
forming an adhesive layer made of a photosensitive thermosetting resin on the wiring substrate;
lowering viscosity of the adhesive layer by heating the adhesive layer to a first temperature zone;
electrically connecting the contact point of the electronic component to the electrode pad through the elastic protrusion, under a state where the viscosity of the adhesive layer is lowered, by pressing a tip of the conductive elastic protrusion formed on the contact point of the electronic component against the electrode pad on the wiring substrate after the electronic component is positioned on the wiring substrate; and
a step of fixing the electronic component onto the wiring substrate by heating the adhesive layer to a second temperature zone higher than the first temperature zone to cure the adhesive layer.

4. The substrate mounting method according to claim 3, further comprising:
a step of forming a film made of a conductive photosensitive thermosetting resin on the electrode pad on the wiring substrate before the step of forming the adhesive layer made of the photosensitive thermosetting resin on the wiring substrate.

5. A substrate mounting method of an electronic component on a wiring substrate, the substrate mounting method comprising steps of:
patterning to form a conductive elastic protrusion on a contact point of the electronic component corresponding to an electrode pad provided at the wiring substrate;
forming an adhesive layer made of a photosensitive thermosetting resin on the contact point of the electronic component or the electrode pad of the wiring substrate;
lowering viscosity of the adhesive layer by heating the adhesive layer to a first temperature zone;
electrically connecting the contact point of the electronic component to the electrode pad through the elastic protrusion, under a state where the viscosity of the adhesive layer is lowered, by pressing a tip of the conductive elastic protrusion formed on the contact point of the electronic component against the electrode pad of the wiring substrate after the electronic component is positioned on the wiring substrate; and
fixing the electronic component onto the wiring substrate by heating the adhesive layer to a second temperature zone higher than the first temperature zone to cure the adhesive layer.

6. The substrate mounting method according to claim 5, wherein, in the step of forming the adhesive layer made of the photosensitive thermosetting resin on the contact point of the electronic component or the electrode pad of the wiring substrate, the adhesive layer is a conductive photosensitive thermosetting resin.

7. The substrate mounting method according to claim 6, further comprising:
a step of forming an adhesive layer made of an insulating photosensitive thermosetting resin between the electronic component and the wiring substrate and between adjacent electrodes.

8. The substrate mounting method according to claim 1,
wherein the elastic protrusion is a resin columnar protrusion coated with a conductor film on a surface of the elastic protrusion that through the conductor film electrically connects the contact point of the electronic component with the electrode pad of the wiring substrate, or wherein the elastic protrusion is a columnar protrusion made of a conductive photoresist.

9. The substrate mounting method according to claim 1, wherein the electronic component is a micro-LED.

10. The substrate mounting method according to claim 8, wherein the electronic component is a micro-LED.

11. An electronic-component-mounted substrate, comprising a wiring substrate on which an electronic component is mounted; the electronic-component-mounted substrate comprising:
the wiring substrate on which an electrode pad is formed;
the electronic component that has a contact point to be connected to the electrode pad; and
a conductive elastic protrusion that is formed on the contact point of the electronic component or the electrode pad of the wiring substrate and electrically connects the contact point to the electrode pad,
wherein the electrode pad of the wiring substrate and the contact point of the electronic component are bonded with a conductive photosensitive thermosetting resin formed in a bonding region.

12. The electronic-component-mounted substrate according to claim 11, wherein an adhesive layer made of an insulating photosensitive thermosetting resin is provided between the electronic component and the wiring substrate and between adjacent electrodes.

13. An electronic-component-mounted substrate, comprising a wiring substrate on which an electronic component is mounted; the electronic-component-mounted substrate comprising:
the wiring substrate on which an electrode pad is formed;
the electronic component that has a contact point to be connected to the electrode pad; and
a conductive elastic protrusion that is formed on the contact point of the electronic component and electrically connects the contact point to the electrode pad,
wherein the wiring substrate and the electronic component are bonded with an insulating photosensitive thermosetting resin, and a tip of the elastic protrusion and the electrode pad are bonded with a conductive photosensitive thermosetting resin formed in a film shape on the electrode pad.

14. An electronic-component-mounted substrate in which an electronic component is mounted on a wiring substrate, the electronic-component-mounted substrate comprising:
the wiring substrate on which an electrode pad is formed;
the electronic component that has a contact point to be connected to the electrode pad; and
a conductive elastic protrusion that is formed on the electrode pad, and electrically connects the contact point to the electrode pad, wherein
the wiring substrate and the electronic component are bonded by an insulating photosensitive thermosetting resin, and
a tip of the elastic protrusion and the contact point are bonded with a conductive photosensitive thermosetting resin formed in a film shape on the contact point.

15. The electronic-component-mounted substrate according to claim 11,
wherein the elastic protrusion is a resin columnar protrusion coated with a conductor film on a surface of the elastic protrusion that through the conductor film electrically connects the contact point of the electronic component with the electrode pad of the wiring substrate, or
wherein the elastic protrusion is a columnar protrusion made of a conductive photoresist.

16. The electronic-component-mounted substrate according to claim 11, wherein the electronic component is a micro-LED.

17. The electronic-component-mounted substrate according to claim 13, wherein the electronic component is a micro-LED.

18. The substrate mounting method according to claim 3,
wherein the elastic protrusion is a resin columnar protrusion coated with a conductor film on a surface of the elastic protrusion that through the conductor film electrically connects the contact point of the electronic component with the electrode pad of the wiring substrate, or
wherein the elastic protrusion is a columnar protrusion made of a conductive photoresist.

19. The substrate mounting method according to claim 5,
wherein the elastic protrusion is a resin columnar protrusion coated with a conductor film on a surface of the elastic protrusion that through the conductor film electrically connects the contact point of the electronic component with the electrode pad of the wiring substrate, or
wherein the elastic protrusion is a columnar protrusion made of a conductive photoresist.

20. The substrate mounting method according to claim 5, wherein the electronic component is a micro-LED.

21. The electronic-component-mounted substrate according to claim 13, wherein the elastic protrusion is a resin columnar protrusion coated with a conductor film on a surface of the elastic protrusion that through the conductor film electrically connects the contact point of the electronic component with the electrode pad of the wiring substrate, or
wherein the elastic protrusion is a columnar protrusion made of a conductive photoresist.

22. The electronic-component-mounted substrate according to claim 14, wherein the elastic protrusion is a resin columnar protrusion coated with a conductor film on a surface of the elastic protrusion that through the conductor film electrically connects the contact point of the electronic component with the electrode pad of the wiring substrate, or
wherein the elastic protrusion is a columnar protrusion made of a conductive photoresist.

23. The electronic-component-mounted substrate according to claim 14, wherein the electronic component is a micro-LED.
